(19) United States
(12) Patent Application Publication
(10) Pub. No.: US 2026/0073116 A1
(43) Pub. Date: Mar. 12, 2026

(54) PARALLEL CREATION OF VIA MESHES IN AN INTEGRATED CIRCUIT

(71) Applicant: International Business Machines Corporation, Armonk, NY (US)

(72) Inventors: Robert John Allen, Jericho, VT (US); Ronald Dennis Rose, Essex Junction, VT (US); Christian Roth, Holzgerlingen (DE)

(21) Appl. No.: 18/826,287

(22) Filed: Sep. 6, 2024

(51) Int. Cl. G06F 30/394; G06F 30/398

(52) U.S. Cl. CPC G06F 30/394; G06F 30/398

(57) ABSTRACT

Aspects of the invention include parallel creation of via meshes in an integrated circuit. Aspects include obtaining a plurality of via mesh creation jobs for an integrated circuit, obtaining existing wires and design rules for the integrated circuit, and partitioning the plurality of via mesh creation jobs into a plurality of sets of jobs, wherein the jobs in each set have a proximity to at least one another job in the set that is less than a threshold distance. Aspects also include assigning each of the plurality of sets of jobs to different processing units and creating, by each of the different processing units, a via mesh for each of the jobs in the assigned set of jobs.

### BACKGROUND

The present invention generally relates to integrated circuit development, and more specifically, to the parallel creation of via meshes in an integrated circuit.

The development of an integrated circuit (i.e., chip) involves several stages from design through fabrication. Some aspects of the development are performed iteratively to ensure that the chip that is ultimately manufactured meets all design requirements. In addition, aspects of the design may be performed in a hierarchical manner. An exemplary organization of a chip is as a set of interconnected cells. Each cell includes a number of interconnected components that allow the cell to serve a specific function (e.g., OR gate, NAND gate). Cells may be standard cells selected from a library to perform a specific function.

The interconnection of cells is through wires routed over multiple levels (i.e., metal layers) with vias (i.e., vertical interconnections) facilitating connections among the stacked metal layers. Timing of the chip may be improved by using higher level metal layers that can carry thicker metal wires. However, this timing improvement must be balanced with the increased density that would result from routing too many interconnections at higher metal layers. This is because increased density increases interference and negatively affects chip performance. Each cell may have different pin layouts and different placement options in relation to the power grid of the particular chip. Placement refers to the particular location within the chip and affects routability. Routing refers to the path (e.g., wire widths, metal layers) used for the interconnection. A cell is not routable if, based on a particular placement, it cannot be interconnected with other cells in a way that meets timing, power, and other requirements.

### SUMMARY

Embodiments of the present invention are directed to methods for parallel creation of via meshes during integrated circuit development. A non-limiting example computer-implemented method includes obtaining a plurality of via mesh creation jobs for an integrated circuit, obtaining existing wires and design rules for the integrated circuit, and partitioning the plurality of via mesh creation jobs into a plurality of sets of jobs, wherein the jobs in each set have a proximity to at least one another job in the set that is less than a threshold distance. The method also includes assigning each of the plurality of sets of jobs to different processing units and creating, by each of the different processing units, a via mesh for each of the jobs in the assigned set of jobs.

Other embodiments of the present invention implement features of the above-described computer systems and computer program products for the parallel creation of via meshes during integrated circuit development.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1 illustrates a computing environment according to one or more embodiments;

FIG. 2 illustrates a three-dimensional representation of a via mesh according to one or more embodiments of the invention;

FIG. 3 illustrates a layout of an integrated circuit design including a conflict graph according to one or more embodiments of the invention;

FIG. 4 illustrates a process flow of a method for parallel creation of via meshes during integrated circuit development according to one or more embodiments of the invention;

FIG. 5 illustrates a process flow of a method for parallel creation of via meshes during integrated circuit development according to one or more embodiments of the invention;

FIG. 6 illustrates a block diagram of a system to perform parallel creation of via meshes during integrated circuit development according to one or more embodiments; and

FIG. 7 illustrates a flow diagram of a method of fabricating an integrated circuit according to one or more embodiments.

The diagrams depicted herein are illustrative. There can be many variations to the diagrams or the operations described therein without departing from the spirit of the invention. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

### DETAILED DESCRIPTION

As previously noted, the cells that make up a chip are interconnected to perform the overall functionality of the chip. Each cell involves an interconnection of components that, together, perform the function of that cell (e.g., multiplication, AND gate). A via mesh provides multiple conductive pathways from one or more points in one layer to one or more points in another layer. At the first level, the via mesh includes interconnected shapes (i.e., wires and vias) that connect to a pin terminal comprised of a single pin or a set of disjoint pins that are logically treated as one pin. On each subsequent layer, one or more straps, which are conductive strips, form conductive pathways that are connected to straps on adjacent layers through one or more vias. While the straps within a layer are oriented parallel to each other, the straps of adjacent layers may be oriented in a different (e.g., orthogonal) direction relative to each other or may be parallel. A router that connects one or more pins of the cell to pins of other cells, which may or may not include a via mesh, only connects to the strap at the highest level of the via mesh. The number of layers from the one or more pins to the highest level defines the height of the via mesh. The redundancy afforded by the straps and vias results in a reduction in resistance of the connection from the one or more pins to the upper layers. The number of straps and vias determines the resistance. A decrease in resistance is referred to as an increase in strength of the via mesh.

A via mesh is a configuration of multiple interconnected vias and wires designed to significantly reduce resistance and enhance timing. Via meshes are formed in integrated circuits (ICs) for electrical connections between different layers of the board or chip. Implementing via meshes is a part of the physical design process of ICs to achieve timing closure. Timing closure refers to a part of the design process of ICs and is the process of ensuring that all timing requirements of the IC are met, meaning that all electrical signals are propagated through the circuit within the required time constrains. To achieve timing closure, the design process ensures that the IC operates correctly at an intended clock speed to meet performance specifications. The process for timing closure often requires multiple iterations of placement and routing thus refining the design to eliminate any timing violations. For large scale designs, creating hundreds of thousands of via meshes involves numerous steps, which can take hours of computational time to compute sequentially.

Typically, the design process of via meshes in ICs is an iterative, sequential process that takes into account logical design principles, continually refined to optimize both electrical and thermal performance as well as ensuring timing closure. This process begins with an initial logical design that outlines the functional requirements and desired performance characteristics. During a floor-planning phase, the overall layout is established, and preliminary considerations for via placement are made based on these logical design truths. As the design progresses into the placement and routing stage, the initial via designs are implemented to connect various components across different layers. This stage is highly iterative; designers continually adjust via placements to optimize signal paths, reduce impedance mismatches, and minimize crosstalk. Each adjustment is guided by logical principles of electrical performance, ensuring that the design adheres to the intended signal integrity and power distribution requirements. The iterative nature of this process allows for continuous improvement, as each iteration brings the design closer to the optimal configuration. Various verification steps are included in this iterative process. These verification steps validate that the design complies with manufacturing rules and accurately reflects the logical design. Any discrepancies or violations identified during these checks necessitate further iterations of via placement and routing adjustments.

The iterative design process for via meshes in ICs is time-consuming and resource-intensive, owing to the complexity and precision required at each stage. Each iteration involves multiple steps, including initial layout, placement and routing, verification, and performance analysis, which collectively demand significant computational power and designer expertise.

Embodiments relate to a parallel process and system for via mesh design aimed at reducing computation time by allowing multiple via meshes to be designed simultaneously. In one or more embodiments of the invention, the IC can be partitioned into sections based on, for example, minimum distance requirements, and each section via mesh design can be processed in parallel resulting in reduced computation time compared to the larger scale sequential processing typically performed. The design process for each section of the IC is performed on a separate thread of a processor and can be iteratively processed to ensure an optimized via mesh design for the section of the IC.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

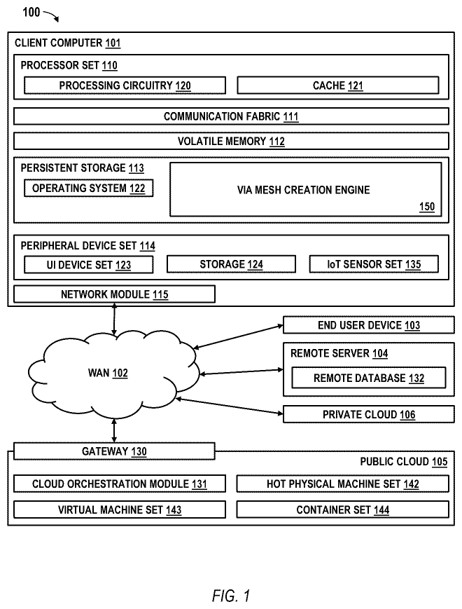

FIG. 1 illustrates a computing environment 100, according to an embodiment. Computing environment 100 contains an example of an environment for the execution of at least some of the computer code involved in performing the inventive methods, such as an via mesh creation engine 150 for performing optimization of via mesh specifications during integrated circuit development. In addition to via mesh creation engine 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and via mesh creation engine 150, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips.

Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in via mesh creation engine 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid-state storage devices. Operating system 122 may take several forms, such as various known proprietary operating systems or open-source Portable Operating System Interface-type operating systems that employ a kernel. The code included in via mesh creation engine 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images. ” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

According to one or more embodiments, the computing environment 100 can provide for remote data storage. For example, the computer 101 can be a cloud storage system or other suitable system for storing data that is accessible to a user remotely, such as by accessing the computer 101 using the end user device 103. That is, a user can send a user operation (also referred to as a “user request”) from the end user device 103 to the computer 101 via the WAN 102. Although the user operation may appear to be simple, such as uploading an object to a cloud storage system, the complications of operating a cloud computing system often have side effects and produce ancillary data, which may be consumed by both the operator of the system (e.g., the computer 101) and by users or other components of the cloud architecture (e.g., the computing environment 100). Ancillary data may be created by user operations that trigger the creation of the ancillary data. Ancillary data may be resource consumption information, notification data, and/or the like, including combinations and/or multiples thereof. Data for an independent event may be inferred from another event (e.g., event to update resource consumption information for an entity in a system also means that the total consumption information for the oner of the entity is also updated).

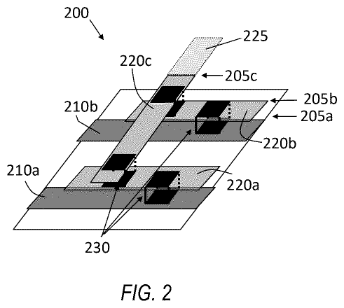

Referring now to FIG. 2, a three-dimensional representation of an exemplary via mesh 200 is shown. The via mesh 200 includes pins 210a, 210b (generally referred to as 210) that are shown on a first layer 205a (generally referred to as layer 205). Straps 220a, 220b (generally referred to as 220) are shown on the second layer 205b. As FIG. 2 indicates, a via 230 connects each pin 210 to a corresponding strap 220. In exemplary embodiments, the pins 210 and straps 220 on adjacent layers may be oriented orthogonally. Another strap 220c is shown at the third layer 205c, which is the top layer of the exemplary via mesh 200. The strap 220c on the third layer 205c is orthogonal to the straps 220a, 220b on the second layer 205b. The number of layers 205 defines the height of the via mesh 200.

Vias 230 facilitate a connection between the pins 210 on the first layer 205a and the straps 220a and 220b on the second layer 205b and additional vias facilitate a connection between each of the straps 220a and 220b on the second layer 205b and the strap 220c at the third layer 205c. The straps 220 and vias 230 make up the via mesh 200. A routing tool, referred to as a router, connects the pins 210 of the cell 235, through the via mesh 200 of the cell 235, to one or more other cells through a net. Specifically, the router connects the cell 235 to the net only at the top level (i.e., the third layer 205c in the example shown) with the wire 225. As previously noted, the via mesh 200 (e.g., the straps 220 and vias 230) provides redundancy in the connection from the net to the pins 210. Increased redundancy is proportional to increased strength of the via mesh 200 and decreased resistance.

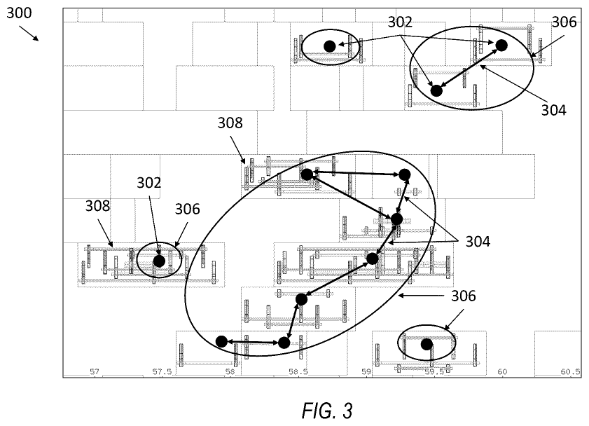

Referring now to FIG. 3, a layout of an integrated circuit 300 design including a conflict graph according to one or more embodiments of the invention is shown. The integrated circuit 300 serves as the primary structure within which various components interact to facilitate the parallel creation of via meshes. The integrated circuit 300 includes multiple layers and interconnected elements that contribute to the overall functionality and performance of the circuit. The layout of the integrated circuit 300 is designed to optimize the placement and routing of vias and wires, ensuring efficient signal transmission and minimal interference.

The nodes 302 within the integrated circuit 300 represent a set of via meshes that needs to be created for the integrated circuit design. The via mesh 308 in the integrated circuit 300 is a configuration of multiple interconnected vias and wires designed to reduce resistance and enhance timing. The via mesh 308 provides multiple conductive pathways between different layers of the circuit, ensuring reliable and efficient signal transmission.

In exemplary embodiments, one or more nodes 302 are connected by edges 304 defining a conflict graph. In exemplary embodiments, two nodes that are separated by less than a threshold distance are connected to one another via an edge 304 and nodes 302 that are separated by more than the threshold distance are not connected via edges 304. The group 306 within the integrated circuit 300 refers to a collection of nodes 302 that are connected to one another via edges 304. Groups 306 are used to organize and manage the complexity of the circuit design, allowing for more efficient processing and optimization. The partitioning of the integrated circuit 300 into groups 306 facilitates parallel processing and optimization, as the via mesh creation for the nodes 302 of different groups 306 can be processed independently while maintaining the integrity of the overall design.

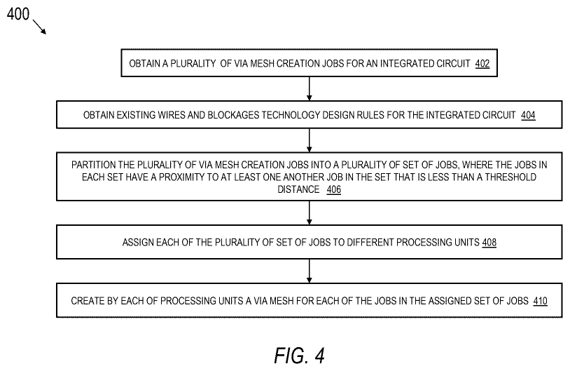

Referring now to FIG. 4 a method 400 for parallel creation of via meshes in an integrated circuit is shown. In exemplary embodiments, the method 400 is performed by the via mesh creation engine 150 of FIG. 1. The method 400 begins with obtaining a plurality of via mesh creation jobs for an integrated circuit 402. This step involves collecting multiple tasks that need to be performed to create via meshes within the integrated circuit. These tasks are referred to as via mesh creation jobs and are necessary for establishing the vertical interconnections between different metal layers in the integrated circuit. In exemplary embodiments, each via mesh creation job is part of a via mesh creation job set represented by a node 302 in the integrated circuit 300 shown in FIG. 3.

The next step in the method 400 is obtaining existing wires and blockages technology design rules for the integrated circuit 404. This step involves gathering information about the current wiring layout and any blockages that may exist within the integrated circuit. Additionally, the design rules that govern the technology used in the integrated circuit are also obtained. These rules include specifications for wire widths, spacing, and other parameters that are adhered to during the via mesh creation process.

Following this, the method 400 involves partitioning the plurality of via mesh creation jobs into a plurality of sets of jobs, where the jobs in each set have a proximity to at least one another job in the set that is less than a threshold distance 406. This step ensures that the via mesh creation jobs are grouped based on their physical proximity within the integrated circuit. By grouping jobs that are close to each other, the method can optimize the processing and reduce the likelihood of spacing violations between the via meshes. In exemplary embodiments, the partitioning includes connecting nodes 302 that are separated by less than a threshold distance to one another via edges 304 to form groups and creating a set of jobs corresponding to each group 306. In exemplary embodiments, the threshold distance is a distance between a first job and a second job of the plurality of via mesh creation jobs for which a spacing violation is likely to occur.

In exemplary embodiments, the number of jobs assigned to each of the plurality of sets of jobs is at least one and at most a maximum number. By limiting the number of jobs assigned to each set to a maximum number, the method ensures that the workload is evenly distributed among the processing units. This prevents any single processing unit from becoming a bottleneck due to an excessive number of jobs, thereby enhancing the overall efficiency and speed of the via mesh creation process. Additionally, this ensures that we have enough job sets such that all processing units are utilized, maximizing the computational resources available. This balanced distribution of jobs across processing units leads to a more efficient parallel processing environment, reducing the total computation time required for creating via meshes in the integrated circuit.

The method 400 then proceeds to assign each of the plurality of sets of jobs to different processing units 408. Each set of via mesh creation jobs is allocated to a separate processing unit, enabling parallel processing of the jobs. This parallel processing approach significantly reduces the overall computation time required to create the via meshes, as multiple processing units can work simultaneously on different sets of jobs. In exemplary embodiments, the sperate processing unit may be separate processing cores on a single processor or entirely separate processors.

The method 400 involves creating, by each of the processing units, a via mesh for each of the jobs in the assigned set of jobs 410. Each processing unit generates the via meshes for the jobs in the assigned set, based on the existing wires and design rules obtained earlier. This step ensures that the via meshes are created efficiently and in compliance with the design specifications, resulting in a well-optimized integrated circuit layout. In exemplary embodiments, the via mesh for each of the jobs in the assigned set of jobs is created based at least in part on the existing wires and design rules for the integrated circuit.

In exemplary embodiments, each of the different processing units are configured to serially create a via mesh for each of the jobs in the assigned set of jobs. By configuring each of the different processing units to serially create a via mesh for each of the jobs in the assigned set of jobs, the method ensures that each processing unit can handle its assigned tasks independently and sequentially. This approach allows for a more controlled and organized creation of via meshes, reducing the complexity of managing parallel tasks within a single processing unit. It also helps in maintaining the integrity of the design by ensuring that each via mesh is created in a step-by-step manner, adhering to the design rules and existing wires for the integrated circuit. This serial execution within each processing unit can be particularly advantageous in scenarios where the design rules and existing wires are highly complex, as it allows for meticulous adherence to these constraints without the risk of conflicts that might arise from simultaneous operations. Additionally, this method can simplify debugging and error correction, as any issues can be traced back to specific steps within the serial process, making it easier to identify and rectify problems.

An example of performing the method involves a scenario where the plurality of via mesh creation jobs includes one hundred via mesh creation jobs that are partitioned into fifteen sets, with each set having a maximum size of ten via mesh creation jobs per set. In this example, the one hundred via mesh creation jobs are partitioned into fifteen sets, with each set containing up to ten via mesh creation jobs. The partitioning ensures that the jobs in each set are physically close to one another within the integrated circuit, optimizing the processing and reducing the likelihood of spacing violations between the via meshes. Each of the fifteen sets of via mesh creation jobs is allocated to a separate processing unit, enabling parallel processing of the jobs. This parallel processing approach significantly reduces the overall computation time required to create the via meshes, as multiple processing units can work simultaneously on different sets of jobs. Each processing unit generates the via meshes for the jobs in its assigned set, based on the existing wires and design rules obtained earlier.

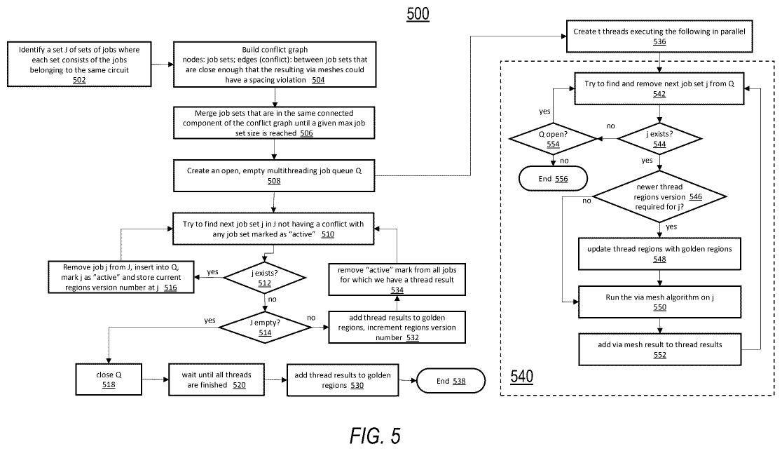

Referring now to FIG. 5, a flowchart of a method 500 for creating via meshes in an integrated circuit that utilizes parallel processing of groups of via mesh jobs is shown. In exemplary embodiments, the method 400 is performed by the via mesh creation engine 150 of FIG. 1.

Several blocks of method 500, i.e. 516, 530, 532, 546 and 548 refer to the term ‘region’ which is a data structure to store the geometrical representation of wires, vias, pins and blockages. The via mesh algorithm in block 550 relies on it to efficiently determine if potential vias or straps for the via mesh are free of spacing violations to already existing wires, vias, pins and blockages. Each thread has its own independent copy of the regions data structure. Synchronization between the ‘golden’ regions containing the combined result of all threads and the thread regions containing only the thread's results is done in blocks 532 and 548 relying on a version number maintained in block 516 and 532. In exemplary embodiments, the regions are used to ensure that the results from parallel processing threads are consistent and free of conflicts before being consolidated into the final design. This helps maintain the integrity and quality of the integrated circuit design throughout the parallel processing and optimization stages.

The method 500 begins with identifying a set J of via mesh creation jobs where each set consists of the via mesh creation jobs belonging to the same circuit 502. This step ensures that jobs related to the same circuit are grouped together for efficient processing. Next, as shown at block 504, the method 500 includes building a conflict graph for the set J of via mesh creation jobs. In the conflict graph, each node represents a set of via mesh creation jobs, and edges (conflicts) exist between via mesh creation jobs that are close enough that the resulting via meshes could have a spacing violation. This step helps identify potential conflicts that need to be managed during the via mesh creation process. The method 500 then proceeds to merge job sets, or nodes, that are in the same connected component of the conflict graph until a given max job set size is reached 506. This step ensures that job sets are combined appropriately to optimize the processing workload while avoiding conflicts.

Next as shown at block 508, the method 500 includes creating an open, empty multithreading job queue Q. This queue will be used to manage the distribution of jobs to different processing threads. At block 510, the method then tries to find the next job set j in J that does not have a conflict with any job set marked as ‘active’. If such a job set is found, the method proceeds to block 516 and removes job j from J, inserts the job set into Q, marks j as ‘active,’ and annotates j with the current region's version number. If no such job set is found, the method proceeds to block 514 and checks if J is empty. If J is empty, the method proceeds to block 518 and closes Q 518. Next, the method 500 waits until all threads are finished, as shown at block 520. Once all threads are finished, the method adds thread results to golden regions, as shown at block 530, and ends and block 538.

If J is not empty, the method proceeds to block 532 and adds thread results to the golden regions and increments the region's version number. Next, the method then removes the ‘active’ mark from all jobs for which a thread result exists, as shown at block 534.

As shown at block 536, the method 500 includes creating t threads to execute the steps shown in block 540 in parallel. At block 542, each thread tries to find and remove the next job set j from Q. At decision block 554, the method 500 determine if Q is open and at decision block 544 the method 500 determines if job set j exists. If j does not exist and Q is not open, the method 500 proceeds to block 556 and ends. At decision block 546, the method 500 determines if a newer thread region's version is required for j by checking if the regions' version number that j is annotated with is larger than the current thread region's version number. If a newer version is required, the thread updates thread regions with golden regions, as shown at block 548. The thread then runs the via mesh algorithm on j, as shown at block 550, and adds the via mesh result to thread results, as shown at block 552. In exemplary embodiments, the method 500 ensures that all threads are synchronized and that the results are consolidated into the golden regions before concluding the process.

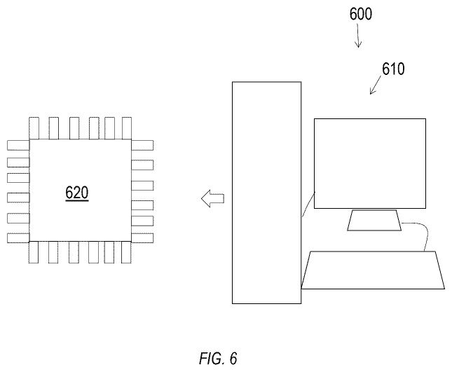

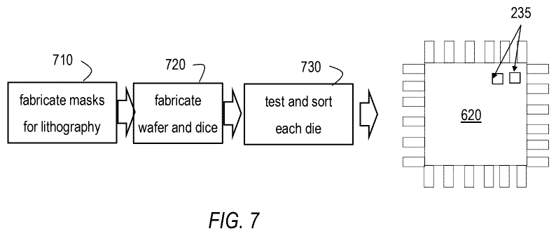

FIG. 6 is a block diagram of a system 600 to perform creating via meshes in an integrated circuit according to one or more embodiments. The system 600 includes processing circuitry 610 used to generate the circuit design that is ultimately fabricated into an integrated circuit 320. The steps involved in the fabrication of the integrated circuit 620 are well-known and briefly described herein. Once the physical layout is finalized, based, in part, on the circuit design optimization according to one or more embodiments, the finalized physical layout is provided to a foundry. Masks are generated for each layer of the integrated circuit based on the finalized physical layout. Then, the wafer is processed in the sequence of the mask order. The processing includes photolithography and etch. This is further discussed with reference to FIG. 7

Particularly, FIG. 7 is a flow diagram of a method of fabricating an integrated circuit according to one or more embodiments. Once the physical design data is obtained, based, in part, on performing circuit design optimization as described herein, the integrated circuit 620 can be fabricated according to known processes that are generally described with reference to FIG. 6. Generally, a wafer with multiple copies of the final design is fabricated and cut (i.e., diced) such that each die is one copy of the integrated circuit 620. At block 710, the processes include fabricating masks for lithography based on the finalized physical layout. At block 720, fabricating the wafer includes using the masks to perform photolithography and etching. Once the wafer is diced, testing and sorting each die is performed, at block 730, to filter out any faulty die.

Embodiments include methods for the parallel creation of via meshes in an integrated circuit, which offers significant technical benefits over traditional sequential and iterative approaches. Traditional methods for creating via meshes are time-consuming and computationally intensive, as they process each via mesh creation job sequentially, often requiring multiple iterations to optimize the design. This invention introduces a parallel processing approach that partitions the via mesh creation jobs into sets based on their physical proximity within the integrated circuit. Each set of jobs is then assigned to different processing units, enabling simultaneous processing of multiple via meshes. The parallel processing method provides several technical benefits that include reduced computation time, improved design efficiency, enhanced performance, scalability, and resource utilization.

In embodiment, by distributing the via mesh creation jobs across multiple processing units, the invention significantly reduces the overall computation time required to create via meshes. This is particularly beneficial for large-scale designs with hundreds of thousands of via meshes. In one embodiment, the method optimizes the design process by grouping jobs based on their proximity, reducing the likelihood of spacing violations and ensuring compliance with design rules. This leads to a more efficient and streamlined design process. In one embodiment, the parallel creation of via meshes allows for better optimization of signal paths, reducing resistance and improving timing. This results in a more robust and high-performance integrated circuit. In exemplary embodiments, the parallel processing approach is highly scalable, making it suitable for complex and large-scale integrated circuit designs. It can efficiently handle the increased computational demands of modern integrated circuit development. In exemplary embodiments, by leveraging multiple processing units, the invention makes better use of available computational resources, leading to more efficient and cost-effective design processes. Overall, the parallel creation of via meshes in an integrated circuit provides a significant advancement in the field of integrated circuit design by introducing a parallel processing method that enhances the speed, efficiency, and performance of via mesh creation, addressing the limitations of traditional sequential methods.

While the foregoing is directed to embodiments of the present disclosure, other and further embodiments of the present disclosure may be devised without departing from the basic scope thereof, and the scope thereof is determined by the claims that follow.

What is claimed is:

1. A computer-implemented method for parallel creation of via meshes in an integrated circuit, the method comprising:
obtaining a plurality of via mesh creation jobs for an integrated circuit;
obtaining existing wires and design rules for the integrated circuit;
partitioning the plurality of via mesh creation jobs into a plurality of sets of jobs, wherein the jobs in each set have a proximity to at least one another job in the set that is less than a threshold distance;
assigning each of the plurality of sets of jobs to different processing units; and
creating, by each of the different processing units, a via mesh for each of the jobs in the assigned set of jobs.

2. The computer-implemented method of claim 1, wherein the via mesh for each of the jobs in the assigned set of jobs is created based at least in part on the existing wires and design rules for the integrated circuit.

3. The computer-implemented method of claim 1, wherein a number of jobs assigned to each of the plurality of sets of jobs is at least one and at most a maximum number.

4. The computer-implemented method of claim 1, wherein the threshold distance is a distance between a first job and a second job of the plurality of via mesh creation jobs for which a spacing violation is likely to occur.

5. The computer-implemented method of claim 1, wherein the different processing units are configured to execute commands in parallel.

6. The computer-implemented method of claim 1, wherein each of the different processing units are configured to serially create a via mesh for each of the jobs in the assigned set of jobs.

7. The computer-implemented method of claim 1, wherein partitioning the plurality of via mesh creation jobs into a plurality of sets of jobs includes generating a conflict graph having nodes representing each of the plurality of via mesh creation jobs and edges connecting nodes that have are separated by less than the threshold distance.

8. A system comprising:
a memory having computer readable instructions; and
one or more processors for executing the computer readable instructions, the computer readable instructions controlling the one or more processors to perform operations comprising:
obtaining a plurality of via mesh creation jobs for an integrated circuit;
obtaining existing wires and design rules for the integrated circuit;
partitioning the plurality of via mesh creation jobs into a plurality of sets of jobs, wherein the jobs in each set have a proximity to at least one another job in the set that is less than a threshold distance;
assigning each of the plurality of sets of jobs to different processing units; and
creating, by each of the different processing units, a via mesh for each of the jobs in the assigned set of jobs.

9. The system of claim 8, wherein the via mesh for each of the jobs in the assigned set of jobs is created based at least in part on the existing wires and design rules for the integrated circuit.

10. The system of claim 8, wherein a number of jobs assigned to each of the plurality of sets of jobs is at least one and at most a maximum number.

11. The system of claim 8, wherein the threshold distance is a distance between a first job and a second job of the plurality of via mesh creation jobs for which a spacing violation is likely to occur.

12. The system of claim 8, wherein the different processing units are configured to execute commands in parallel.

13. The system of claim 8, wherein each of the different processing units are configured to serially create a via mesh for each of the jobs in the assigned set of jobs.

14. The system of claim 8, wherein partitioning the plurality of via mesh creation jobs into a plurality of sets of jobs includes generating a conflict graph having nodes representing each of the plurality of via mesh creation jobs and edges connecting nodes that have are separated by less than the threshold distance.

15. A computer program product comprising a computer readable storage medium having program instructions embodied therewith, the program instructions executable by a processor to cause the processor to perform operations comprising:
obtaining a plurality of via mesh creation jobs for an integrated circuit;
obtaining existing wires and design rules for the integrated circuit;
partitioning the plurality of via mesh creation jobs into a plurality of sets of jobs, wherein the jobs in each set have a proximity to at least one another job in the set that is less than a threshold distance;
assigning each of the plurality of sets of jobs to different processing units; and
creating, by each of the different processing units, a via mesh for each of the jobs in the assigned set of jobs.

16. The computer program product of claim 15, wherein the via mesh for each of the jobs in the assigned set of jobs is created based at least in part on the existing wires and design rules for the integrated circuit.

17. The computer program product of claim 15, wherein a number of jobs assigned to each of the plurality of sets of jobs is at least one and at most a maximum number.

18. The computer program product of claim 15, wherein the threshold distance is a distance between a first job and a second job of the plurality of via mesh creation jobs for which a spacing violation is likely to occur.

19. The computer program product of claim 15, wherein the different processing units are configured to execute commands in parallel.

20. The computer program product of claim 15, wherein each of the different processing units are configured to serially create a via mesh for each of the jobs in the assigned set of jobs.
